(19) United States
(12) Patent Application Publication
(10) Pub. No.: US 2025/0253194 A1
(43) Pub. Date: Aug. 7, 2025

(54) IN-SITU THROUGH SILICON VIA CHARACTERIZATION AND MONITORING IN SEMICONDUCTOR DEVICES

(71) Applicant: QUALCOMM Incorporated, San Diego, CA (US)

(72) Inventors: Dharani Kumar SRINIVASAN, Chennai (IN); Praveen RAGHURAMAN, Chennai (IN)

(21) Appl. No.: 18/434,390

(22) Filed: Feb. 6, 2024

(51) Int. Cl. H01L 21/66; G01R 31/28; H01L 23/48; H01L 25/065

(52) U.S. Cl. CPC H01L 22/34; G01R 31/2853; H01L 22/14; H01L 23/481; H01L 25/0657; H01L 2225/06541

(57) ABSTRACT

Aspects of the disclosure provides various systems, apparatuses, and techniques for performing in-situ monitoring and validation of through silicon via (TSV) used to connect chiplets. A semiconductor device includes a plurality of chiplets and at least one TSV connecting two or more of the plurality of chiplets. At least one of the plurality of chiplets include TSV monitoring circuitry can perform in-situ validation of the at least one TSV. The TSV monitoring circuitry can apply a stimulus input signal to the at least one TSV. The TSV monitoring circuitry can receive a stimulus output signal from the at least one TSV, in response to the stimulus input signal. The TSV monitoring circuitry can monitor one or more electrical characteristics of the at least one TSV based on the stimulus output signal and the stimulus input signal.

### TECHNICAL FIELD

The present disclosure relates generally to integrated circuit technology and more particularly to characterization of through silicon vias in semiconductor devices.

### BACKGROUND

A computer system can include one or multiple cores or processors implemented by one or more individual integrated circuit devices. An integrated circuit device can include one or more semiconductor dies, which may include various components, for example, processing cores, graphical processors, interfaces, memory, communication devices, etc. Multiple integrated circuit dies may be included in the same package, and on-package interconnects can be used to connect the dies together. In some examples, an integrated circuit die can be referred to as a chiplet. A chiplet is a functional unit that performs certain specific tasks or provides certain functionality within an integrated circuit device containing multiple chiplets.

Through silicon via (TSV) is a vertical interconnection technology used in semiconductor packaging to create pathways or electrical connections (e.g., signal connections) between chiplets through a silicon substrate. A TSV can be a vertical metal connection that passes through the entire thickness of a silicon wafer of the chiplet. This is different from other interconnection methods that rely on planar (horizontal) metal traces on the surface of the die or substrate. TSVs can enable the stacking of multiple semiconductor devices (e.g., chiplets), thus facilitating increased integration and performance in electronic systems and semiconductor devices. TSVs enable shorter paths for signals, reducing signal propagation delays, and improving overall performance. TSVs can facilitate three-dimensional (3D) integration of multiple chiplets or dies, allowing for increased functionality and reduced footprint. Further, TSVs can enable high-bandwidth communication between vertically stacked chiplets, supporting faster data transfer rates. TSV technology is commonly used in advanced packaging techniques, such as 3D and 2.5D integrated circuits.

### SUMMARY

The following presents a summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a form as a prelude to the more detailed description that is presented later.

Certain aspects of the disclosure relate to integrated circuit (IC) devices that include multiple chiplets or dies that are connected using through silicon via (TSV). In some aspects, an IC device (e.g., a system-on-chip (SoC)) can continuously monitor the operational state and condition of the chiplets and TSV during runtime.

One aspect of the disclosure provides a semiconductor device that includes a plurality of chiplets and at least one through silicon via (TSV) connecting two or more of the plurality of chiplets. At least one of the plurality of chiplets includes TSV monitoring circuitry configured to perform in-situ validation of the at least one TSV. The TSV monitoring circuitry is configured to: apply a stimulus input signal to the at least one TSV; receive a stimulus output signal from the at least one TSV, in response to the stimulus input signal; monitor one or more electrical characteristics of the at least one TSV based on the stimulus output signal and the stimulus input signal.

One aspect of the disclosure provides a method of validating a semiconductor device including two or more chiplets connected together by at least one through silicon via (TSV). A stimulus input signal is applied into the at least one TSV. A stimulus output signal is received from the at least one TSV, in response to the stimulus input signal. One or more electrical characteristics of the at least one TSV are monitored based on the stimulus output signal and the stimulus input signal.

One aspect of the disclosure provides a semiconductor device including two or more chiplets connected together by at least one through silicon via (TSV). The semiconductor device includes means for applying a stimulus input signal into the at least one TSV; means for receiving a stimulus output signal from the at least one TSV, in response to the stimulus input signal; and means for monitoring one or more electrical characteristics of the at least one TSV based on the stimulus output signal and the stimulus input signal.

One aspect of the disclosure provides a first chiplet that includes at least one through silicon via (TSV) configured to connect the first chiplet with a second chiplet, the chiplets being included in a same stack. The first chiplet includes a TSV monitoring circuitry configured to perform in-situ validation of the at least one TSV. The TSV monitoring circuitry is configured to: apply a stimulus input signal to a first end of the at least one TSV; receive a stimulus output signal from a second end of the at least one TSV, the stimulus output signal corresponding to an altered version of the stimulus input signal due to a physical characteristic of the TSV; and determine that the at least one TSV being defective in response to a difference between the stimulus output signal and the stimulus input signal being greater than a predetermined threshold.

### BRIEF DESCRIPTION OF THE DRAWINGS

FIG. 1 illustrates a semiconductor apparatus including multiple interconnected components according to some aspects of the disclosure.

FIG. 2 illustrates certain aspects of an apparatus that can be constructed using chiplets according to some aspects of the disclosure.

FIG. 3 illustrates an exemplary apparatus in which multiple chiplets are stacked vertically on a substrate according to some aspects of the disclosure.

FIG. 4 illustrates exemplary chiplets configured with an in-situ through silicon via (TSV) monitoring circuitry according to some aspects of the disclosure.

FIG. 5 illustrates an exemplary TSV monitoring circuitry according to some aspects of the disclosure.

FIG. 6 illustrates an exemplary functional diagram of a signal characterization circuitry according to some aspects of the disclosure.

FIG. 7 is a block diagram of an exemplary chiplet with a TSV monitoring circuitry according to some aspects of the disclosure.

FIG. 8 illustrates a block diagram of an exemplary decoder circuitry for testing TSVs according to some aspects of the disclosure.

FIG. 9 illustrates a startup timeline of a semiconductor device including in-situ TSV monitoring and validation according to aspects of the disclosure.

FIG. 10 a flow chart illustrating an exemplary in-situ TSV validation and monitoring process according to some aspects of the disclosure.

FIG. 11 is a flow chart illustrating a method for validating TSVs in a semiconductor device according to some aspects of the disclosure.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well-known structures and components are shown in block diagram form in order to avoid obscuring such concepts.

Several aspects of the invention will now be presented with reference to various apparatus and methods. These apparatus and methods will be described in the following detailed description and illustrated in the accompanying drawings by various blocks, modules, components, circuits, steps, processes, algorithms, etc. (collectively referred to as “elements”). These elements may be implemented using electronic hardware, computer software, firmware, or any combination thereof. Whether such elements are implemented as hardware or software depends upon the particular application and design constraints imposed on the overall system.

Aspects of the disclosure provide various systems, apparatuses, and techniques for enabling in-situ characterization, validation, and monitoring of a through silicon via (TSV) for connecting one or more chiplets in a semiconductor integrated device. In some aspects, a chiplet can include circuitry onboard that is configured to characterize and validate one or more TSVs in the chiplet. One or more TSVs can be used to connect chiplets together. Some aspects of the disclosure enable techniques for post stacking TSV validation and feedback of TSV characteristics. Some aspects of the disclosure enable techniques for direct current (DC) and alternating current (AC) signal testing of TSVs. Some aspects of the disclosure provide a feedback mechanism of TSV characteristics induced by chiplet operations and/or manufacturing defect and reliability issues.

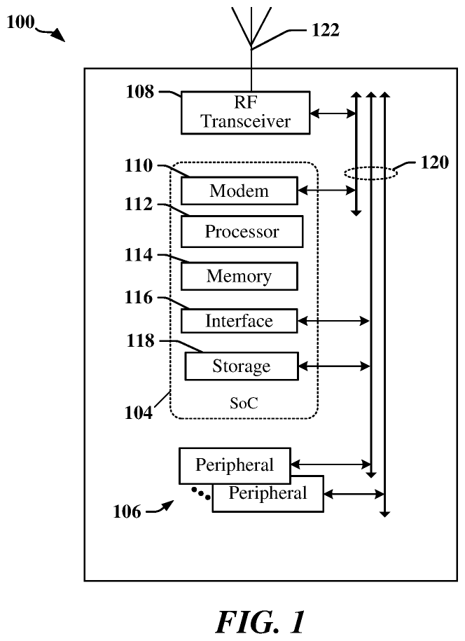

FIG. 1 illustrates an example of an apparatus 100 that includes multiple components that may be implemented using integrated circuit devices, for example, a system-on-chip (SoC). The SoC can include multiple components or dies (e.g., chiplets) with in-situ TSVs monitoring. In some examples, the apparatus may be included within a portable or a wearable device, such as a smartwatch or a mobile device (e.g., smartphone, mobile phone, etc.). In some aspects, the SoC 104 includes various circuitry that can be implemented using one or more dies (e.g., chiplets) arranged in a configuration that can be adapted for use in mobile computing, embedded computing, edge computing, etc. In one example, the apparatus 100 may be configured to support multiple communication technologies, modes, or protocols. In some aspects, the apparatus 100 further includes one or more peripheral devices 106 and a transceiver 108 that cooperate to enable the apparatus to communicate through an antenna 122 with a radio access network, a core access network, the Internet, and/or another network.

In some aspects, the SoC 104 may include various circuitry, for example, one or more processors 112, one or more modems 110, one or more on-board memories (e.g., memory 114), a bus interface circuit 116, and/or other logic circuits or functions. The SoC can be controlled by an operating system that provides an application programming interface (API) layer that enables the one or more processors 112 to execute software modules residing in the on-board memory 114 or other processor-readable data storage 118 provided on the SoC. The software modules may include instructions and data stored in one or more memories (e.g., the on-board memory 114 and/or processor-readable storage 118). The SoC 104 may access its on-board memory 114, the processor-readable storage 118, and/or storage external to the apparatus 100/SoC 104.

In some aspects, the on-board memory 114 and the processor-readable storage 118 (e.g., a non-transitory medium) may include read-only memory (ROM), random-access memory (RAM), electrically erasable programmable ROM (EEPROM), flash memory, or any memory device that can be used in processing systems and computing platforms. The apparatus may include, implement, or have access to a local database or other parameter storage that can maintain operational parameters and other information used to configure and operate the apparatus 100 and/or the SoC 104. The local database may be implemented using registers, a database module, flash memory (e.g., NAND flash), magnetic media, EEPROM, soft or hard disk, or the like. The SoC 104 may also be operably coupled to external devices such as the antenna 122, a display, operator controls, switches or buttons, among other components.

The apparatus 100 may provide an interconnect (e.g., link 120) that enables signal communication between different components (e.g., SoC 104, peripheral 106, and/or 108 RF transceiver). In one example, the SoC 104 may include communication interface circuits 116 coupled to the interconnect. Each of the interface circuits 116 may include a combination of circuits, counters, timers, control logic and other configurable circuits or modules. In one example, certain interconnect interface circuits 116 may be configured to operate in accordance with standards-defined communication specifications or protocols. The apparatus 100 may include or control a power management function that configures and manages the operation of the apparatus 100.

In some aspects, the apparatus 100 may be included in mobile phones, tablet computers, palmtop computers, portable digital assistants (PDAs), portable game consoles, tablets, and other portable electronic devices. The various components or dies (e.g., chiplets) of the apparatus 100 may communicate with each other via one or more intra-chip communication interconnects. In some aspects, the apparatus 100 can be packaged in an integrated circuit (IC) package, which may be referred to as a “semiconductor package” or “chip package.” The IC package typically includes a package substrate and one or more IC chips, dies, chiplets, or other electronic modules mounted to the package substrate to provide electrical connectivity to the IC chips, dies, or chiplets. For example, an IC chip in an IC package may be configured as an SoC. The IC chips are electrically coupled to other IC chips and/or to other components in the IC package through electrical coupling to metal lines in the package substrate. The IC chips can also be electrically coupled to other circuits outside the IC package through electrical connections of external metal interconnects (e.g., solder bumps) of the IC package.

Process technology employed to manufacture semiconductor devices, including IC devices is continually improving. Process technology includes the manufacturing methods used to make IC devices and defines transistor size, operating voltages and switching speeds. Features that are constituent elements of circuits in an IC device may be referred as technology nodes and/or process nodes. The terms technology node, process node, and process technology may be used to characterize a specific semiconductor manufacturing process and corresponding design rules. Faster and more power-efficient technology nodes are being continuously developed through the use of smaller feature size to produce smaller transistors that enable the manufacture of higher-density ICs. Design rules for newer process technology that use low-voltage transistors may preclude the use of higher voltage transistors supported by previous process technology generations. The unavailability of certain higher-voltage transistors may present an impediment to circuit designers for IC devices that include multiple voltage domains.

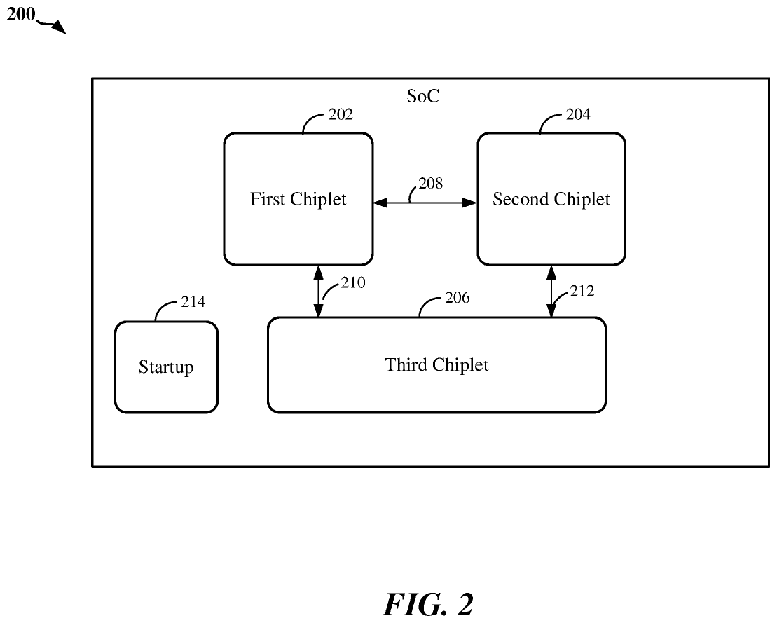

In some aspects, chiplet technology can be used to address some of the performance, power, and size design requirements for complex SoCs used in certain mobile or wearable devices. The block diagram in FIG. 2 illustrates certain aspects of an SoC 200 that can be constructed using chiplets according to some aspects. In one example, the SoC 200 may be the SoC 104 of FIG. 1. The SoC 200 may be configured by selecting a combination of chiplets that implement certain subsystems or distinct functional elements. In the illustrated example, the SoC 200 includes multiple chiplets, for example, a first chiplet 202, a second chiplet 204, and a third chiplet 206 that are connected to each other via interconnects 208, 210, and 212. In other examples, the SoC 200 may include fewer or more than three chiplets as those shown in FIG. 2. The chiplets can be configured to provide various subsystems or functions of the SoC. In some aspects, the interconnects 208, 210, and 212 can include one or more TSVs for connecting the chiplets together.

In some aspects, the SoC 200 can include a startup circuitry 214 configured to perform a startup process of the SoC. The startup process can include initializing the various components, configuring the system, and bringing the entire device into an operational state. For example, the startup process can include initializing the chiplets and configuring various settings, loading necessary software, and initializing the system. The startup process can also include built-in self-test mechanisms that run diagnostic and validation tests during startup to check the integrity of various components and the interconnects (e.g., TSVs). In some aspects, the SoC can continuously monitor the operational state and condition of the chiplets and TSVs during runtime.

In some aspects, the SoC 200 may include a variety of processing engines, such as central processing units (CPUs) with multiple cores, graphical processing units (GPUs), digital signal processors (DSPs), neural processing units (NPUs), wireless transceiver units (also referred to as modems), peripherals, display and imaging interfaces, etc. Each of these subsystems and other functional elements can be implemented as an individual chiplet or as a combination of chiplets (e.g., chiplets 202, 204, and/or 206) connected together using one or more TSVs. The chiplets included in the SoC 200 can be proprietary or may be acquired from a variety of sources. An SoC may be constructed from chiplets manufactured at different process nodes, operated at different voltages, and/or operated at different frequencies.

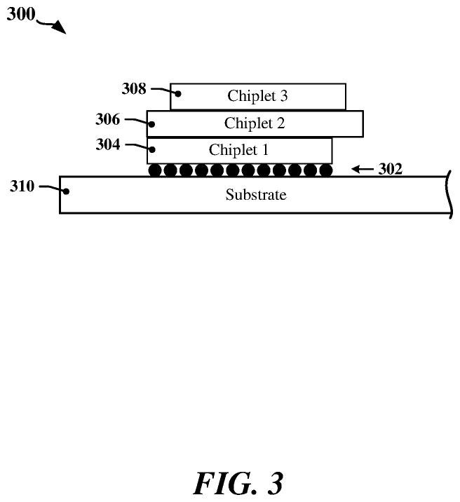

FIG. 3 illustrates an SoC 300 including three exemplary chiplets 304, 306, 308 stacked on a substrate 310. In other examples, some chiplets can be included in stacks that are deployed across the surface of the substrate 310, while other chiplets may be individually mounted on the surface of the substrate 310. In some aspects, chiplets may be mounted on the surface of the substrate using solder balls 302 (e.g., flip chip bumps) that provide electrical and/or thermal coupling between the substrate 310 and the mounted chiplets 304, 306, and 308. An interconnect structure (e.g., one or more TSVs) may be formed that enables die-to-die communication between the chiplets 304, 306, 308, with other chiplets (not shown) mounted on the substrate 310, and with input/output structures that connect the SoC 300 with other circuits, displays, imaging sensors, and other peripherals within an apparatus. In some examples, the SoC 300 may be any of the SoCs described above in relation to FIGS. 1 and 2.

The use of chiplets can reduce the areal size of the substrate 310 and increase three-dimensional packing density. The constituent chiplets may provide complex features and high performance within a smaller form-factor operated at lower power specifications. Moreover, each chiplet may define multiple power domains, operate at different frequencies, and different chiplets may manage power/frequency modes independently. In some instances, two or more chiplets may be operated in mutually exclusive power states. Additionally, operating conditions for an SoC depends on the type, number, and arrangement of chiplets included on the substrate in addition to the modes of operation defined by applications. It is necessary to consider power usage by all chiplets in the SoC in order to ensure compliance with power budgets assigned for an application or device.

In some aspects, the connection between various dies (e.g., chiplets) can include TSVs. The quality of TSVs can impact the performance of the chiplets or SoC. For example, TSV quality can affect signal integrity and hence functionality/performance of the stacked chiplets 304, 306, and 308. TSVs reliability and aging become a concern when the TSVs are used over a longer period. However, current TSV implementations do not provide a methodology for the functional characterization and validation of TSVs (at time of manufacturing and/or aging) in DC and AC perspectives. For example, current manufacturing phases such as pre-bond, mid-bond, and post-bond do not provide granular controllability and observability for TSV validation.

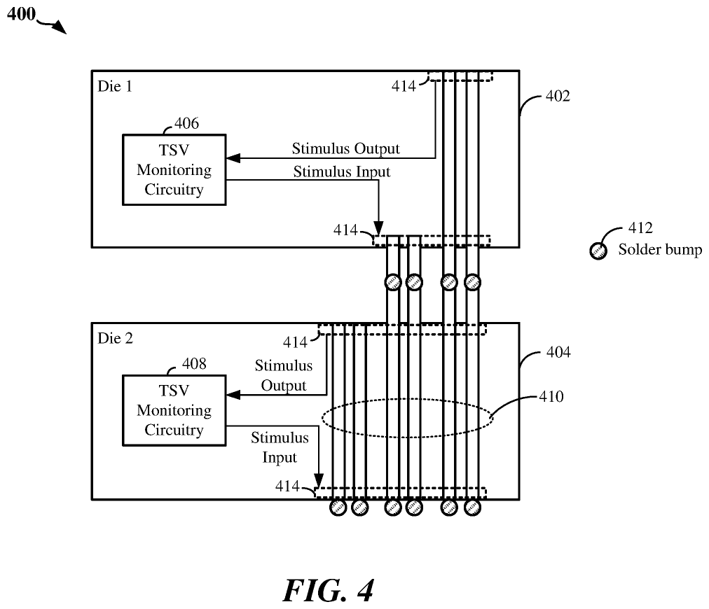

FIG. 4 illustrates exemplary chiplets 400 configured with in-situ TSV monitoring and validation according to some aspects of the disclosure. For example, a chiplet (e.g., chiplets 402 and 404) can include a TSV monitoring circuitry 406/408 that can be configured to perform in-situ characterization, validation, and monitoring of TSVs in the chiplet. While FIG. 4 illustrates a stack including two chiplets, more than two chiplets can be stacked together and connected using TSVs. For example, the chiplets can be any of the chiplets described above in relation to FIGS. 1-3.

In some aspects, the chiplets can be connected together via one or more TSVs 410. Each TSV may be made of an electrically conductive material (e.g., metal). For example, copper is a commonly used material for TSVs due to its excellent electrical conductivity and compatibility with semiconductor manufacturing processes. A chiplet (e.g., chiplet 404) can have TSVs that extend within the chiplet and/or outside of the chiplet to be connected with corresponding TSVs from another chiplet (e.g., chiplet 402). In some examples, the TSVs of adjacent chiplets can be connected together using solder bumps (e.g., micro bumps 412) between the respective terminal points 414 of the TSVs.

In some aspects, the TSV monitoring circuitry enables testing, characterization, and/or validation of the TSVs before and post stacking of the chiplets. For example, the TSV monitoring circuitry can apply a stimulus input (or signal) to the TSVs and/or receive a stimulus output (or signal) from the TSVs at the corresponding termination points of the TSVs. The stimulus input can include an AC signal and/or a DC test signal used for testing the TSVs. In some examples, the AC test signal can include a predetermined square wave signal, sine wave signal, or any suitable AC signal. In one example, the DC test signal can include a reference DC voltage signal. In some aspects, the stimulus signal can include a specific electrical signal or set of signals used for testing and characterizing the TSV's electrical properties and reliability. TSV testing is crucial for ensuring proper functionality, signal integrity, and the overall performance of the chiplets and an SoC including the chiplets. In some aspects, the TSV monitoring circuitry can perform various testing of the TSV, for example, DC mode: open circuit or short circuit measurement based on conductivity or resistivity, AC mode: impedance measurement based on signal reflection (e.g., time domain reflectometry). The specific choice of test signals depends on the objectives of the testing and the properties of the TSV being evaluated. In some aspects, a combination of testing signals can be used to ensure that the TSV can meet the desired specifications and performance needed for the intended applications.

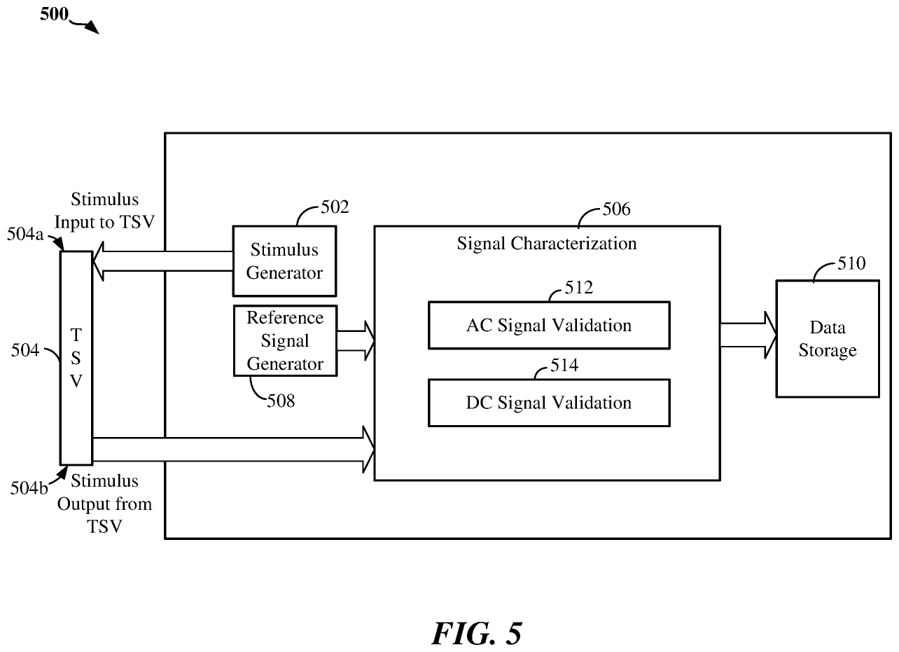

FIG. 5 illustrates exemplary TSV monitoring circuitry 500 according to some aspects of the disclosure. In one example, the TSV monitoring circuitry 500 can correspond to the TSV monitoring circuitry illustrated in FIG. 4. The TSV monitoring circuitry 500 can include a stimulus generator 502 that can generate and apply a stimulus input signal to test one or more TSVs (e.g., TSV 504). In some aspects, the stimulus input signal can include a AC signal (e.g., sine wave, square wave) and/or a DC signal for the testing, characterization, and/or validation of the TSV. The TSV monitoring circuitry 500 can apply the stimulus input signal to a first end 504a of the TSV (e.g., TSV 504), and the TSV monitoring circuitry 500 can receive the stimulus output signal from a second end 504b of the TSV. The stimulus output signal is an altered version of the stimulus input signal when it passes through the TSV 504. Depending on the quality and characteristics of the TSV, the TSV can introduce propagation delay, signal attenuation, distortion, noise and interference, reflections, etc., to the stimulus input signal when the stimulus signal passes through the TSV.

In some aspects, the TSV monitoring circuitry 500 can include signal characterization circuitry 506 that can receive and analyze the stimulus output signal from the TSV. The TSV monitoring circuitry 500 can include a reference signal generator 508 that outputs reference signals (e.g., AC and DC reference signals) that are used by the signal characterization circuitry 506 for TSV validation and characterization. For example, the signal characterization circuitry 506 can compare the stimulus output signal with the reference signal to monitor, characterize, and validate the condition of the TSV. The TSV monitoring circuitry 500 can store the test results in a data storage 510. For example, the data storage 510 can include random-access memory (RAM), electrically erasable programmable ROM (EEPROM), flash memory, or any memory device that can store data. In some examples, the data storage 510 can include memory storage located inside and/or outside the TSV monitoring circuitry 500. In some aspects, the signal characterization circuitry 506 includes AC signal validation circuitry 512 and DC signal validation circuitry 514. The AC signal validation circuitry can be configured to perform various AC signal testing functions. The DC signal validation circuitry 514 can be configured to perform various DC signal testing functions. The AC signal testing functions and DC signal testing functions will be described in more detail below.

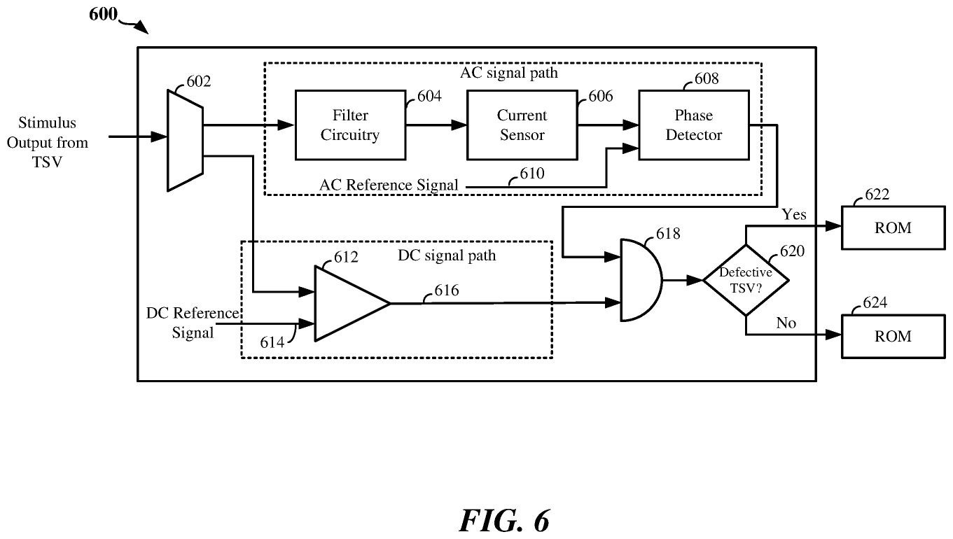

FIG. 6 illustrates an exemplary functional block diagram of signal characterization circuitry 600 according to some aspects of the disclosure. In one example, the signal characterization circuitry 600 can be implemented in the TSV monitoring circuitry 500 of FIG. 5. The signal characterization circuitry 600 can be configured to perform various functions including characterization, validation, and monitoring of TSVs (e.g., TSVs 208/210/212 of FIG. 2, TSVs 410 of FIG. 4) used for interconnecting chiplets. The signal characterization circuitry 600 can include a selector 602 (e.g., demultiplexer, switch) that receives a stimulus output signal from a TSV (e.g., TSV 504 of FIG. 5). Depending on the type of stimulus output signal, the selector 602 can route the output signal to an AC signal path or a DC signal path. For example, the signal characterization circuitry 600 can use the AC signal path to test an AC stimulus output signal, and use the DC signal path to test a DC stimulus output signal.

In some aspects, the AC signal path can include filter circuitry 604, current sensor circuitry 606, and phase detector circuitry 608. In one example, the filter circuitry 604 can contain one or more resistors and one or more capacitors that together form a filter circuit (e.g., a high pass filter, a low pass filter, a bandpass filter). Depending on the configuration, the filter circuitry 604 can pass the signal in the interested frequency/frequencies and filter out other unwanted frequencies. In some examples, the cutoff frequency of the filter circuitry 604 can be configurable. In one example, the filter circuitry can include a low-pass filter that allows a frequency below a cut-off frequency to pass through, while attenuating higher frequencies. In one example, the filter circuitry can include a high-pass filter that allows a signal higher than a cut-off frequency to pass through, while attenuating lower frequencies.

In some aspects, the current sensor circuitry 606 can be configured to measure the current flowing in the AC signal path. For example, the current sensor circuitry 606 can be configured to monitor and quantify the amount of current passing through a TSV. In some aspects, the phase detector circuitry 608 can be configured to measure the phase of the stimulus output signal from the TSV. For example, the phase detector circuitry 608 can compare the phase of the stimulus output signal with a reference signal (e.g., AC reference signal 610) to determine the phase difference between them. For example, the AC reference signal 610 can be the same as the stimulus input signal of the TSV or a signal with the same phase of the stimulus input signal. A phase difference greater than a threshold can indicate that the TSV has a large signal distortion that can be an indication of a non-nominal TSV condition or malfunction. In some aspects, the phase detector circuitry 608 can output a signal that indicates the measured phase of the stimulus output signal. In some aspects, the phase detector circuitry 608 can output a signal that indicates whether or not the TSV is defective or not nominal, for example, based on the measurements of the current sensor 606 and the phase detector 608.

In some aspects, the DC signal path can include comparator circuitry (e.g., a signal comparator 612) that compares the stimulus output signal with a reference signal (e.g., DC reference signal 614). For example, the signal comparator 612 can produce an output 616 that indicates the relative relationship or difference (e.g., a DC level difference between them) between the stimulus output signal and the DC reference signal. The signal comparator 612 can determine if the stimulus output signal from the TSV is greater than, equal to, or less than the DC reference signal. A DC level difference greater than a predetermined threshold can indicate that the TSV has a malfunction, is defective, or not nominal. For example, the signal comparator 612 can output a signal that indicates whether or not the TSV is defective based on the comparison of the input signals.

The signal characterization circuitry 600 can include circuitry (e.g., a combiner 618 or logic gate) that receives the outputs from the AC signal path and DC signal path. For example, the combiner 618 can receive the output signal from the phase detector 608 and the output signal from the comparator 612. The combiner 618 can output a signal to indicate whether the tested TSV is defective or not, based on the outputs of the AC signal path and the DC signal path. If at least one of the output signals of the AC signal path and DC signal path indicates that the TSV is defective, the signal characterization circuitry 600 can store information of the defective TSV in a first storage 622 (e.g., a ROM). If neither of the output signals of the AC signal path and DC signal path indicates that the TSV is defective, the signal characterization circuitry 600 can store the information of the tested non-defective TSV in a second storage 624 (e.g., a ROM). In some aspects, the data in the data storages 622 and 624 can be used for troubleshooting of the chiplet that includes the signal characterization circuitry 600. In some aspects, the first data storage 622 and the second data storage 624 may be included in the same data storage device or distributed in different storage devices. In some aspects, the data stored in the data storage can include information for identifying the TSV tested and the corresponding test results. For example, each TSV may be identified by a unique code or number, and the associated test results may include the current measurements, phase measurements, DC level, etc.

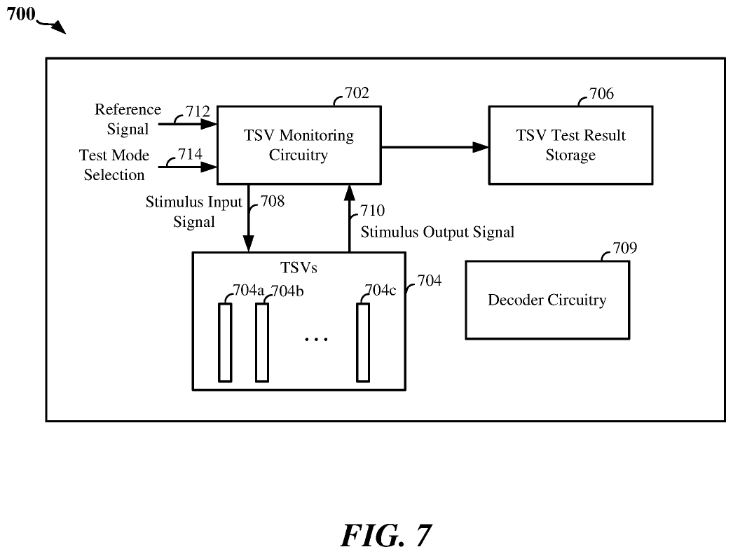

FIG. 7 is a block diagram of an exemplary chiplet 700 with TSV monitoring circuitry according to some aspects of the disclosure. The chiplet 700 can be provided with TSV monitoring circuitry 702 for testing and monitoring one or more TSVs 704 (three exemplary TSVs 704a, 704b, 704c shown in FIG. 7). The chiplet 700 can store the test results of the TSVs in a data storage 706. For example, the TSV monitoring circuitry 702 may correspond to the TSV monitoring circuitry described in relation to FIGS. 5 and 6. The one or more TSVs 704 may be any of the TSVs described in relation to FIGS. 1-6.

As described above, the TSV monitoring circuitry can generate a stimulus input signal 708. For example, the stimulus input signal can include an AC test signal and/or a DC test signal. The TSV monitoring circuitry 702 can apply the stimulus input signal 708 to the TSVs 704 sequentially and/or in parallel. In one example, the TSV monitoring circuitry 702 can apply the stimulus input signal 708 to one TSV at a time in sequence such that the TSVs are tested one at a time. In one example, the TSV monitoring circuitry 702 can send the stimulus input signal 708 to multiple TSVs in parallel such that multiple TSVs can be tested at the same time. In some aspects, the TSV monitoring circuitry 702 can send the stimulus input signal 708 to the TSVs in groups sequentially with each group including a different subset of the TSVs. In this case, the stimulus input signal 708 can be applied to the TSVs in parallel in the same group. Each group of the TSVs can include one or more TSVs. In some aspects, the TSV monitoring circuitry 702 may include decoder circuitry 709 configured to select the TSV(s) for testing in sequence and/or parallel.

The TSV monitoring circuitry 702 can receive a stimulus output signal 710 from the TSVs. The output signal 710 corresponds to an altered version of the stimulus input signal 708 when the signal passes through the tested TSV. A TSV receives the stimulus input signal 708 at a first end, and the stimulus output signal exits at the other end of the TSV. The stimulus output signal 710 can be compared with a reference signal 712. The reference signal 712 can include an AC reference signal 610 and/or a DC reference signal 614 as described above in relation to FIG. 6. The TSV monitoring circuitry 702 can test the stimulus output signal 710 using the AC reference and/or DC reference signal based on a test mode selection signal 714. For example, the test mode selection signal 714 can be set to a first state or a second state. The first state can cause the TSV monitoring circuitry 702 to perform an AC test of the stimulus output signal using an AC reference signal. The second state can cause the TSV monitoring circuitry 702 to perform a DC test of the stimulus output signal 710 using a DC reference signal.

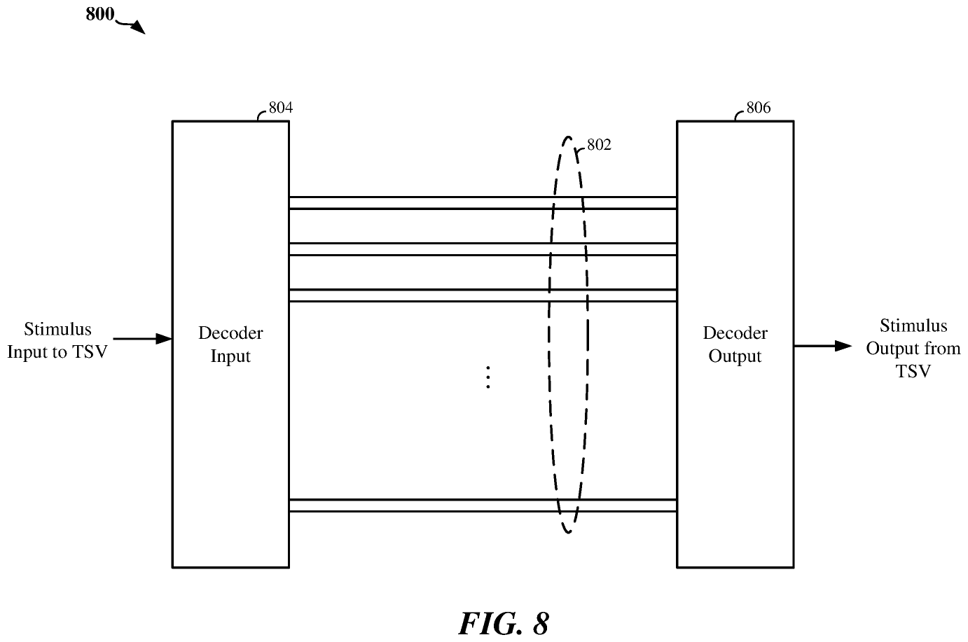

FIG. 8 illustrates a block diagram of exemplary decoder circuitry 800 for testing TSVs according to some aspects of the disclosure. The decoder circuitry 800 can be used to select one or more TSVs 802 in a chiplet for testing. The TSVs 802 may be any of the TSVs described above in relation to FIGS. 1-7. In some aspects, the decoder circuitry 800 can be included in any of the TSV monitoring circuitry described above in relation to FIGS. 1-7. The decoder circuitry 800 can include input circuitry 804 that receives a stimulus input signal for testing the TSVs 802. The input circuitry 804 can be configured to apply the stimulus input signal to the TSVs one-by-one in sequence, in a plurality of groups in sequence, or all TSVs in parallel. Each group of the TSVs may include one or more TSVs that receive the stimulus input signal in parallel.

The decoder circuitry 800 can include output circuitry 806 that receives stimulus output signals from the TSVs 802. The output circuitry 806 can send the stimulus output signals to a signal characterization circuitry as described above in relation to FIGS. 5 and 6. When multiple TSVs are tested in parallel, the output circuitry can combine the signals from the TSVs so that the signal characterization circuitry can monitor and validate the TSVs in group.

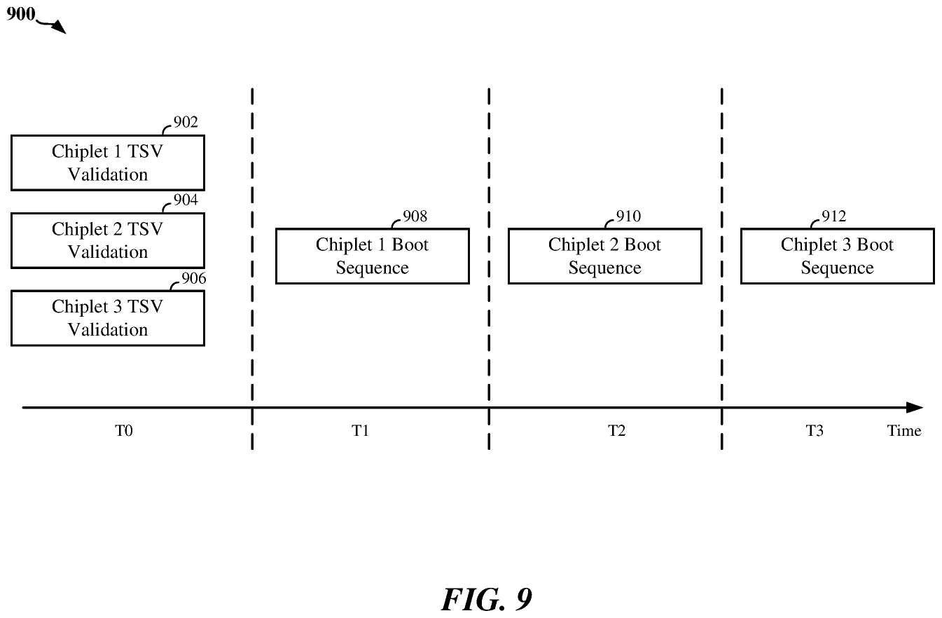

FIG. 9 is a diagram illustrating a startup timeline 900 of a semiconductor device including multiple chiplets according to aspects of the disclosure. In one example, the device may be an SoC as described above in relation to FIGS. 1-3 or a semiconductor device that includes multiple dies (e.g., chiplets) that are connected together by TSVs. In some aspects, the semiconductor device includes TSV monitoring circuitry as described above in relation to FIGS. 1-8 that enables in-situ validation of TSVs post stacking or during manufacturing of the device.

The startup timeline starts in a first time period (TO) in which TSV validation may be performed on each of the chiplets (e.g., chiplet 1, chiplet 2, and chiplet 3). The TSV validation may include TSV testing processes described above in relation to FIGS. 1-8. In one example, the device can include three chiplets (chiplet 1, chiplet 2, and chiplet 3) that perform their respective TSV validations (e.g., TSV validations 902, 904, and 906 shown in FIG. 9) after the device is started or powered up in TO. The TSV validation processes of the chiplets can have the same or different durations, start at the same or different start time, and/or finish at the same or different finish time. In some examples, two or more of the TSV validation processes can overlap (e.g., partially or completely). In some examples, two or more of the TSV validation processes do not overlap.

If the chiplets can finish and pass TSV validation, the device can proceed with the boot sequences of the chiplets. In one example, the device can start the boot sequence 908 of the first chiplet in the time period T1, the boot sequence 910 of the second chiplet in the time period T2, and the boot sequence 912 of the third chiplet in the time period T3. In some examples, two or more of the boot sequences can overlap (e.g., partially or completely). In some examples, two or more of the boot sequences do not overlap. Two or more of the boot sequences may have the same or different durations. Each chiplet boot sequence can include procedures specific to the design of the chiplet. In some aspects, the start of a boot sequence may depend on the completion of another boot sequence. For example, the boot sequence 910 can start in response to the completion of the boot sequence 908, and the boot sequence 912 can start in response to the completion of the boot sequence 910. In some examples, the boot sequences can start independently without depending on the other boot sequences.

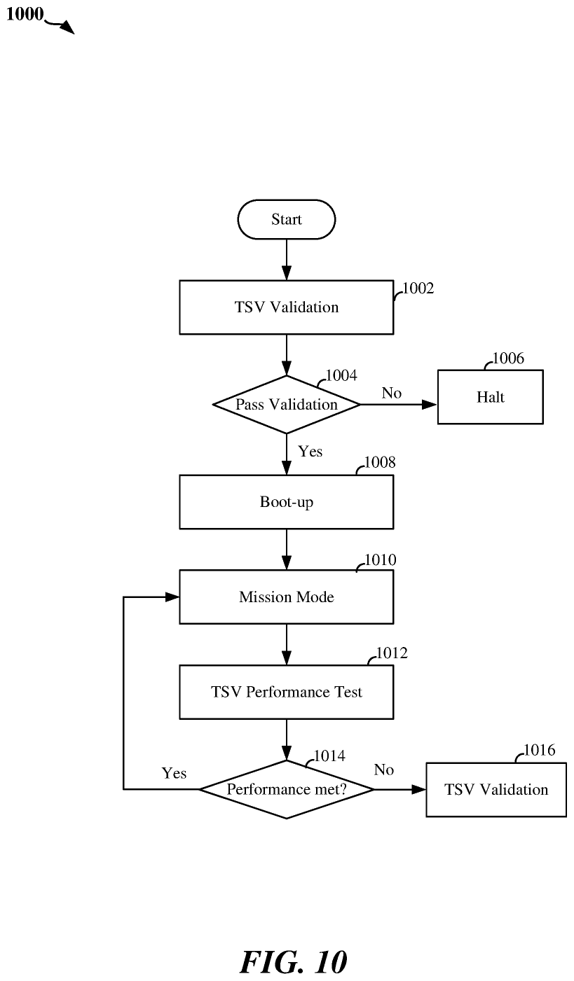

FIG. 10 is a flow chart illustrating an exemplary in-situ TSV validation process 1000 of a chiplet according to some aspects of the disclosure. A chiplet can include TSV monitoring circuitry and one or more TSVs as described above in relation to FIGS. 1-8. For example, the process 1000 can be performed at any of the SoCs described above in FIGS. 1-8 or a device using chiplets.

At 1002, the chiplet can perform TSV validation, for example, as described above in relation to FIGS. 5-8. For example, the chiplet can perform TSV validation after it is powered up or after a reset. At 1004, the chiplet can determine whether or not the chiplet can pass the TSV validation test. At 1006, when the chiplet fails TSV validation, the chiplet can halt the startup process. For example, the chiplet can store the TSV validation result in a data storage (e.g., storage 510) for later troubleshooting and analysis. In some aspects, the chiplet can be included in a device (e.g., SoC) that has a startup circuitry (e.g., startup circuitry 214 of FIG. 2) that can access the validation results.

At 1008, when the chiplet can pass TSV validation, the chiplet can proceed with its boot-up sequence. For example, the boot-up sequence can configure various settings, load necessary software, and initialize the chiplet such that it can perform its designed functions. At 1010, after the chiplet completes the boot-up sequence, the chiplet can be in a mission mode or operating mode in which the chiplet can perform operations for its intended function. Some examples of chiplet function can include, but are not limited to, data processing, data storage and management, graphics rendering, machine learning, signal processing, input/output functions, data communication, wireless communication, sensor operations, security functions, analog signals processing, power management, etc.

At 1012, while the chiplet is in the mission mode, the chiplet can perform TSV performance tests at a certain interval, periodically, aperiodically, or any suitable time. For example, the chiplet can perform a TSV performance test to monitor the performance of the TSVs. In one example, a performance test involves execution of TSV validation multiple times. In one example, the chiplet can support in-system testing and reliability monitoring of TSV when the SoC is in the mission mode. At 1014, the chiplet can determine whether the TSVs meet the expected performance requirement. When the TSVs can meet the expected performance requirement, the chiplet can continue to stay in the mission mode. At 1016, when any TSV fails to meet the expected performance requirement, the chiplet can trigger TSV validation to determine which TSV(s) is/are causing the performance issue.

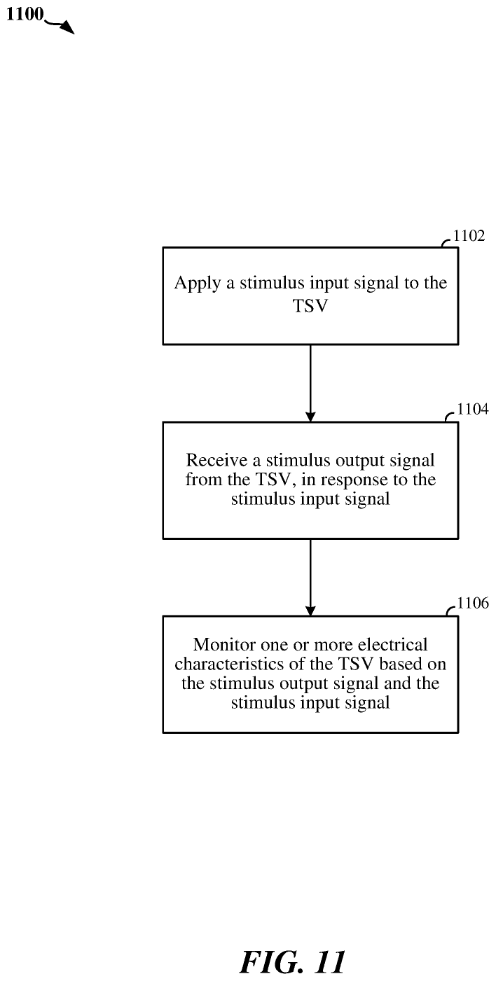

FIG. 11 is a flow chart 1100 illustrating a method for validating TSVs of a semiconductor device according to some aspects of the disclosure. The device can include two or more chiplets connected by one or more TSVs. In some instances, the method can be implemented using any of SoC that uses TSVs for chiplets interconnection. In some examples, the method can be implemented at a TSV monitoring circuitry embedded in a chiplet or SoC.

At 1102, a stimulus input signal can be applied to at least one TSV of a chiplet. For example, the TSV monitoring circuitry 406/408 can provide a means (e.g., stimulus generator 502) to generate and apply the stimulus input signal to the TSV(s). In some aspects, the stimulus input signal can include an AC signal and/or DC signal. For example, the AC signal can be a sine wave or a square wave, or any predetermined AC signal. In one example, the semiconductor device can include the decoder circuitry 800 that provides a means to select one or more TSVs of a chiplet to receive the stimulus input signal.

At 1104, a stimulus output signal can be received from the at least one TSV, in response to the stimulus input signal. For example, the TSV monitoring circuitry 406/408 can provide a means (e.g., signal characterization circuitry 506) to receive the stimulus output signal. In some instances, the TSV monitoring circuitry applies the stimulus input signal to a first end of the TSV, and receive the stimulus output signal from a second end of the TSV. The stimulus output signal is an altered version of the stimulus input signal when it passes through the TSV. Depending on the quality and characteristics of the TSV, the TSV can introduce propagation delay, signal attenuation, distortion, noise and interference, reflections, etc., to the stimulus input signal when it passes through the TSV. In one example, the decoder circuitry 800 can provide a means to select one or more TSVs from which the stimulus output signal is received.

At 1106, one or more electrical characteristics of the at least one TSV can be monitored based on the stimulus output signal and the stimulus input signal. For example, the TSV monitoring circuitry 406/408 can provide a means (e.g., AC signal validation 512 and DC signal validation 514) to monitor the one or more electrical characteristics of the at least one TSV. In one example, the TSV monitoring circuitry can compare the stimulus output signal with a reference signal (e.g., a AC reference signal 610 and/or a DC reference signal 614). In one example, the TSV monitoring circuitry can compare the stimulus output signal with the stimulus input signal. Based on the difference between the reference signal and the stimulus output signal, the TSV monitoring circuitry can determine the one or more electrical characteristics of the at least one TSV. In some aspects, the TSV monitoring circuitry can determine whether or not the TSV is defective or not nominal based on the output stimulus signal. For example, when the difference (e.g., current flow, phase, DC level, etc.) between the stimulus output signal and the reference signal is greater than a threshold, the TSV monitoring circuitry can consider the tested TSV being defective.

Some implementation examples are described in the following numbered clauses:

Clause 1: A semiconductor device comprising: a plurality of chiplets; and at least one through silicon via (TSV) connecting two or more of the plurality of chiplets, at least one of the plurality of chiplets comprising TSV monitoring circuitry configured to perform in-situ validation of the at least one TSV, the TSV monitoring circuitry being configured to: apply a stimulus input signal to the at least one TSV; receive a stimulus output signal from the at least one TSV, in response to the stimulus input signal; and monitor one or more electrical characteristics of the at least one TSV based on the stimulus output signal and the stimulus input signal.

Clause 2: The semiconductor device of clause 1, wherein the TSV monitoring circuitry comprises: an alternating current (AC) signal path configured to perform AC signal validation of the at least one TSV based on the stimulus output signal; and a direct current (DC) signal path configured to perform DC signal validation of the at least one TSV based on the stimulus output signal.

Clause 3: The semiconductor device of clause 2, wherein the AC signal path comprises at least one of: current sensor circuitry configured to measure an electrical current corresponding to the stimulus output signal; phase detector circuitry configured to compare a reference signal with the stimulus output signal to measure a phase of the stimulus output signal; or filter circuitry configured to filter out or pass through one or more predetermined frequencies.

Clause 4: The semiconductor device of clause 2, wherein the DC signal path comprises comparator circuitry configured to compare the stimulus output signal with a DC reference signal.

Clause 5: The semiconductor device of any of clauses 1-4, wherein the TSV monitoring circuitry is configured to monitor the one or more electrical characteristics of the at least one TSV in at least one of: a startup timeline of the semiconductor device; or a runtime of the semiconductor device.

Clause 6: The semiconductor device of any of clauses 1-4, wherein the at least one TSV comprises a plurality of TSVs, and wherein the TSV monitoring circuitry is further configured to monitor the one or more electrical characteristics of the plurality of TSVs concurrently.

Clause 7: The semiconductor device of any of clauses 1-4, wherein at least one TSV comprises a plurality of TSV; and wherein the TSV monitoring circuitry is further configured to monitor the one or more electrical characteristics of the plurality of TSVs in sequence.

Clause 8: The semiconductor device of any of clauses 1-4, further comprising: a data storage configured to store a test result of the at least one TSV, the test result indicating whether or not the at least one TSV is defective.

Clause 9: The semiconductor device of any of clauses 1-4, wherein the TSV monitoring circuitry is further configured to monitor the one or more electrical characteristics of the at least one TSV in a stack comprising the plurality of chiplets.

Clause 10: A method of validating a semiconductor device comprising two or more chiplets connected together by at least one through silicon via (TSV), the method comprising: applying a stimulus input signal into the at least one TSV; receiving a stimulus output signal from the at least one TSV, in response to the stimulus input signal; and monitoring one or more electrical characteristics of the at least one TSV based on the stimulus output signal and the stimulus input signal.

Clause 11: The method of clause 10, wherein the monitoring comprises: performing AC signal validation of the at least one TSV based on the stimulus output signal; and performing DC signal validation of the at least one TSV based on the stimulus output signal.

Clause 12: The method of clause 11, wherein the performing AC signal validation comprises at least one of: measuring an electrical current corresponding to the stimulus output signal; comparing a reference signal with the stimulus output signal to detect a phase of the stimulus output signal; or filtering out or passing through one or more predetermined frequencies.

Clause 13: The method of clause 11, wherein the performing DC signal validation comprises: comparing the stimulus output signal with a DC reference signal.

Clause 14: The method of any of clauses 10-13, further comprising: monitoring the one or more electrical characteristics of the at least one TSV in at least one of: a startup time of the semiconductor device before commencing a boot-up sequence of the two or more chiplets; or a runtime of the semiconductor device.

Clause 15: The method of any of clauses 10-13, wherein the at least one TSV comprises a plurality of TSVs, the method further comprising: monitoring the one or more electrical characteristics of the plurality of TSVs concurrently.

Clause 16: The method of any of clauses 10-13, wherein the at least one TSV comprises a plurality of TSVs, the method further comprising: monitoring the one or more electrical characteristics of the plurality of TSVs in sequence.

Clause 17: The method of any of clauses 10-13, further comprising: storing a test result of the at least one TSV in a data storage, the test result indicating whether or not the at least one TSV is defective.

Clause 18: The method of any of clauses 10-13, further comprising: monitoring the one or more electrical characteristics of the at least one TSV in a stack comprising the two or more chiplets.

Clause 19: A semiconductor device comprising two or more chiplets connected together by at least one through silicon via (TSV), comprising: means for applying a stimulus input signal into the at least one TSV; means for receiving a stimulus output signal from the at least one TSV, in response to the stimulus input signal; and means for monitoring one or more electrical characteristics of the at least one TSV based on the stimulus output signal and the stimulus input signal.

Clause 20: The semiconductor device of clause 19, wherein the means for monitoring comprises: means for performing AC signal validation of the at least one TSV based on the stimulus output signal; and means for performing DC signal validation of the at least one TSV based on the stimulus output signal.

Clause 21: The semiconductor device of clause 20, wherein the means for performing AC signal validation comprises at least one of: means for measuring an electrical current corresponding to the stimulus output signal; means for comparing a reference signal with the stimulus output signal to detect a phase of the stimulus output signal; or means for filtering out or passing through one or more predetermined frequencies.

Clause 22: The semiconductor device of clause 20, wherein the means for performing DC signal validation comprises: means for comparing the stimulus output signal with a DC reference signal.

Clause 23: The semiconductor device of any of clauses 19-22, further comprising: means for monitoring the one or more electrical characteristics of the at least one TSV in at least one of: a startup time of the semiconductor device before commencing a boot-up sequence of the two or more chiplets; or a runtime of the semiconductor device.

Clause 24: The semiconductor device of any of clauses 19-22, wherein the at least one TSV comprises a plurality of TSVs, the semiconductor device further comprising: means for monitoring the one or more electrical characteristics of the plurality of TSVs concurrently.

Clause 25: The semiconductor device of any of clauses 19-22, wherein the at least one TSV comprises a plurality of TSVs, the semiconductor device further comprising: means for monitoring the one or more electrical characteristics of the plurality of TSVs in sequence.

Clause 26: The semiconductor device of any of clauses 19-22, further comprising: means for storing a test result of the at least one TSV in a data storage, the test result indicating whether or not the at least one TSV is defective.

Clause 27: The semiconductor device of any of clauses 19-22, further comprising: means for monitoring the one or more electrical characteristics of the at least one TSV in a stack comprising the two or more chiplets.

Clause 28: A chiplet comprising: at least one through silicon via (TSV) configured to connect the chiplet with another chiplet, the chiplets included in a same stack; and a TSV monitoring circuitry configured to perform in-situ validation of the at least one TSV, the TSV monitoring circuitry being configured to: apply a stimulus input signal to a first end of the at least one TSV; receive a stimulus output signal from a second end of the at least one TSV, the stimulus output signal corresponding to an altered version of the stimulus input signal due to a physical characteristic of the TSV; and determine that the at least one TSV being defective in response to a difference between the stimulus output signal and the stimulus input signal being greater than a predetermined threshold.

Clause 29: The chiplet of clause 28, wherein the TSV monitoring circuitry comprises: an alternating current (AC) signal path configured to perform AC signal validation of the at least one TSV based on the stimulus output signal; and a direct current (DC) signal path configured to perform DC signal validation of the at least one TSV based on the stimulus output signal.

Clause 30: The chiplet of clause 28 or 29, wherein the TSV monitoring circuitry is further configured to monitor one or more electrical characteristics of the at least one TSV in at least one of: a startup time of the chiplet before commencing a boot-up sequence of the chiplet; or a runtime of the chiplet.

It is understood that the specific order or hierarchy of steps in the processes disclosed is an illustration of exemplary approaches. Based upon design preferences, it is understood that the specific order or hierarchy of steps in the processes may be rearranged. Further, some steps may be combined or omitted. The accompanying method claims present elements of the various steps in a sample order, and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” Unless specifically stated otherwise, the term “some” refers to one or more. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed as a means plus function unless the element is expressly recited using the phrase “means for.”

It is understood that the specific order or hierarchy of steps in the processes disclosed is an illustration of exemplary approaches. Based upon design preferences, it is understood that the specific order or hierarchy of steps in the processes may be rearranged. Further, some steps may be combined or omitted. The accompanying method claims present elements of the various steps in a sample order, and are not meant to be limited to the specific order or hierarchy presented.

What is claimed is:

1. A semiconductor device comprising:
a plurality of chiplets; and
at least one through silicon via (TSV) connecting two or more of the plurality of chiplets,
at least one of the plurality of chiplets comprising TSV monitoring circuitry configured to perform in-situ validation of the at least one TSV,
the TSV monitoring circuitry being configured to:
apply a stimulus input signal to the at least one TSV;
receive a stimulus output signal from the at least one TSV, in response to the stimulus input signal; and
monitor one or more electrical characteristics of the at least one TSV based on the stimulus output signal and the stimulus input signal.

2. The semiconductor device of claim 1, wherein the TSV monitoring circuitry comprises:
an alternating current (AC) signal path configured to perform AC signal validation of the at least one TSV based on the stimulus output signal; and
a direct current (DC) signal path configured to perform DC signal validation of the at least one TSV based on the stimulus output signal.

3. The semiconductor device of claim 2, wherein the AC signal path comprises at least one of:
current sensor circuitry configured to measure an electrical current corresponding to the stimulus output signal;
phase detector circuitry configured to compare a reference signal with the stimulus output signal to measure a phase of the stimulus output signal; or
filter circuitry configured to filter out or pass through one or more predetermined frequencies.

4. The semiconductor device of claim 2, wherein the DC signal path comprises comparator circuitry configured to compare the stimulus output signal with a DC reference signal.

5. The semiconductor device of claim 1, wherein the TSV monitoring circuitry is configured to monitor the one or more electrical characteristics of the at least one TSV in at least one of:
a startup timeline of the semiconductor device; or
a runtime of the semiconductor device.

6. The semiconductor device of claim 1,
wherein the at least one TSV comprises a plurality of TSVs, and
wherein the TSV monitoring circuitry is further configured to monitor the one or more electrical characteristics of the plurality of TSVs concurrently.

7. The semiconductor device of claim 1,
wherein at least one TSV comprises a plurality of TSV; and
wherein the TSV monitoring circuitry is further configured to monitor the one or more electrical characteristics of the plurality of TSVs in sequence.

8. The semiconductor device of claim 1, further comprising:
a data storage configured to store a test result of the at least one TSV, the test result indicating whether or not the at least one TSV is defective.

9. The semiconductor device of claim 1, wherein the TSV monitoring circuitry is further configured to monitor the one or more electrical characteristics of the at least one TSV in a stack comprising the plurality of chiplets.

10. A method of validating a semiconductor device comprising two or more chiplets connected together by at least one through silicon via (TSV), the method comprising
applying a stimulus input signal into the at least one TSV;
receiving a stimulus output signal from the at least one TSV, in response to the stimulus input signal; and
monitoring one or more electrical characteristics of the at least one TSV based on the stimulus output signal and the stimulus input signal.

11. The method of claim 10, wherein the monitoring comprises:
performing AC signal validation of the at least one TSV based on the stimulus output signal; and
performing DC signal validation of the at least one TSV based on the stimulus output signal.

12. The method of claim 11, wherein the performing AC signal validation comprises at least one of:
measuring an electrical current corresponding to the stimulus output signal;
comparing a reference signal with the stimulus output signal to detect a phase of the stimulus output signal; or
filtering out or passing through one or more predetermined frequencies.

13. The method of claim 11, wherein the performing DC signal validation comprises:
comparing the stimulus output signal with a DC reference signal.

14. The method of claim 10, further comprising:
monitoring the one or more electrical characteristics of the at least one TSV in at least one of:
a startup time of the semiconductor device before commencing a boot-up sequence of the two or more chiplets; or
a runtime of the semiconductor device.

15. The method of claim 10, wherein the at least one TSV comprises a plurality of TSVs, the method further comprising:
monitoring the one or more electrical characteristics of the plurality of TSVs concurrently.

16. The method of claim 10, wherein the at least one TSV comprises a plurality of TSVs, the method further comprising:
monitoring the one or more electrical characteristics of the plurality of TSVs in sequence.

17. The method of claim 10, further comprising:
storing a test result of the at least one TSV in a data storage, the test result indicating whether or not the at least one TSV is defective.

18. The method of claim 10, further comprising:
monitoring the one or more electrical characteristics of the at least one TSV in a stack comprising the two or more chiplets.

19. A semiconductor device comprising two or more chiplets connected together by at least one through silicon via (TSV), comprising:
means for applying a stimulus input signal into the at least one TSV;
means for receiving a stimulus output signal from the at least one TSV, in response to the stimulus input signal; and
means for monitoring one or more electrical characteristics of the at least one TSV based on the stimulus output signal and the stimulus input signal.

20. The semiconductor device of claim 19, wherein the means for monitoring comprises:
means for performing AC signal validation of the at least one TSV based on the stimulus output signal; and
means for performing DC signal validation of the at least one TSV based on the stimulus output signal.

21. The semiconductor device of claim 20, wherein the means for performing AC signal validation comprises at least one of:
means for measuring an electrical current corresponding to the stimulus output signal;
means for comparing a reference signal with the stimulus output signal to detect a phase of the stimulus output signal; or
means for filtering out or passing through one or more predetermined frequencies.

22. The semiconductor device of claim 20, wherein the means for performing DC signal validation comprises:
means for comparing the stimulus output signal with a DC reference signal.

23. The semiconductor device of claim 19, further comprising:
means for monitoring the one or more electrical characteristics of the at least one TSV in at least one of:
a startup time of the semiconductor device before commencing a boot-up sequence of the two or more chiplets; or
a runtime of the semiconductor device.

24. The semiconductor device of claim 19, wherein the at least one TSV comprises a plurality of TSVs, the semiconductor device further comprising:
means for monitoring the one or more electrical characteristics of the plurality of TSVs concurrently.

25. The semiconductor device of claim 19, wherein the at least one TSV comprises a plurality of TSVs, the semiconductor device further comprising:
means for monitoring the one or more electrical characteristics of the plurality of TSVs in sequence.

26. The semiconductor device of claim 19, further comprising:
means for storing a test result of the at least one TSV in a data storage, the test result indicating whether or not the at least one TSV is defective.

27. The semiconductor device of claim 19, further comprising:
means for monitoring the one or more electrical characteristics of the at least one TSV in a stack comprising the two or more chiplets.

28. A chiplet comprising:
at least one through silicon via (TSV) configured to connect the chiplet with another chiplet, the chiplets included in a same stack; and
a TSV monitoring circuitry configured to perform in-situ validation of the at least one TSV, the TSV monitoring circuitry being configured to:
apply a stimulus input signal to a first end of the at least one TSV;
receive a stimulus output signal from a second end of the at least one TSV, the stimulus output signal corresponding to an altered version of the stimulus input signal due to a physical characteristic of the TSV; and
determine that the at least one TSV being defective in response to a difference between the stimulus output signal and the stimulus input signal being greater than a predetermined threshold.

29. The chiplet of claim 28, wherein the TSV monitoring circuitry comprises:
an alternating current (AC) signal path configured to perform AC signal validation of the at least one TSV based on the stimulus output signal; and
a direct current (DC) signal path configured to perform DC signal validation of the at least one TSV based on the stimulus output signal.

30. The chiplet of claim 28, wherein the TSV monitoring circuitry is further configured to monitor one or more electrical characteristics of the at least one TSV in at least one of:
a startup time of the chiplet before commencing a boot-up sequence of the chiplet; or
a runtime of the chiplet.
